(19) United States
(12) Patent Application Publication
(10) Pub. No.: US 2005/0146269 A1
(43) Pub. Date: Jul. 7, 2005

(54) Gain structure of an LED

(76) Inventor: Wen-Chiang Chiang, Hsin Chuang City (TW)

Correspondence Address: Wen-Chiang Chiang, PO Box 82-144, Taipei, TW

(21) Appl. No.: 10/745,491

(22) Filed: Dec. 29, 2003

(51) Int. Cl. H01L 33/00; H01J 1/62

(52) U.S. Cl. 313/512; 257/99; 257/100

(57) ABSTRACT

A gain structure of an LED is disclosed. The structure comprises an LED seat block, a plurality of square LEDs, and two layered transparent hood, characterized in that the conductive pins of the LEDs are soldered to corresponding conductive wire of the seat block and the first transparent hood covers the tip of the square LEDs, and the tip of the LEDs is provided with a convex lens, the surrounding of the convex lens is protruded to urge the transparent rim of the tip of the LEDs and the external of the first transparent hood is provided with a second transparent hood and the internal surrounding of the second transparent hood is provided with a transparent internal teeth strap, and the center of the top of the second transparent hood is formed into a convex lens.

### BACKGROUND OF THE INVENTION

(a) Technical Field of the Invention

The present invention relates to a gain structure of an LED, and in particular to an LED with stronger lightness as compared to a conventional LED.

(b) Description of The Prior Art

LED devices are now commonly used in everyday life so as to provide lighting and light indication as warning light in various types of vehicles.

FIG. 1 is schematic view of a commonly found LED element. A conductive cylinder 10 is a thermal wire 20 which provides light when it is hot (heated). A glass hood 30 seals the cylinder 10 and the hood 30 is a sealed space for the thermal wire 20. An inert gas is filled. The drawback of the hood 30 is that the glass hood 30 is fragile and it is current exhaustive and the discharged heat is high. In view of the above it is an object of the present invention to provide a gain structure of an LED which overcomes the above drawbacks.

### SUMMARY OF THE INVENTION

Accordingly, it is an object of the present invention to provide an LED seat block, a plurality of square LEDs, and two layered transparent hood, characterized in that the conductive pins of the LEDs are soldered to corresponding conductive wire of the seat block and the first transparent hood covers the tip of the square LEDs, and the tip of the LEDs is provided with a convex lens, the surrounding of the convex lens is protruded to urge the transparent rim of the tip of the LEDs, and the external of the first transparent hood is provided with a second transparent hood and the internal surrounding of the second transparent hood is provided with a transparent internal teeth strap, and the center of the top of the second transparent hood is formed into a convex lens.

Yet another object of the present invention is to provide a gain structure of an LED, wherein the dual-layered transparent hood will not breakable.

Still another object of the present invention is to provide a gain structure of an LED, wherein the surrounding of the transparent hood is a transparent internal teeth strap so that the transmitting light ray provides decorative effect.

Yet a further object of the present invention is to provide a gain structure of an LED, wherein the square LED uses lesser current and the discharged-heat is low.

The foregoing objects and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a conventional schematic view of an LED bulb.

FIG. 2 is a schematic view of a gain structure of an LED in accordance with the present invention.

FIG. 3 is a sectional view of a gain structure of an LED of the present invention.

FIG. 4 is an exploded view of the gain structure of an LED of the present invention.

FIG. 4A is a sectional view taken along line A-A of FIG. 4.

FIG. 4B is a sectional view taken along line B-B of FIG. 4.

FIG. 5 is a schematic view showing a square LED of the gain structure of the LED, covering a first layer rubber material transparent hood of the present invention.

FIGS. 6 and 6A illustrate the gain structure of the LED according to a second preferred embodiment of the present invention.

FIGS. 7 and 7A illustrate the gain structure of the LED according to a third preferred embodiment of the present invention.

FIG. 8 and 8A illustrate the gain structure of the LED according to a fourth preferred embodiment of the present invention.

### DETAILED DESCRIPTION OF THE PREFERRED EMBODIMENT

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

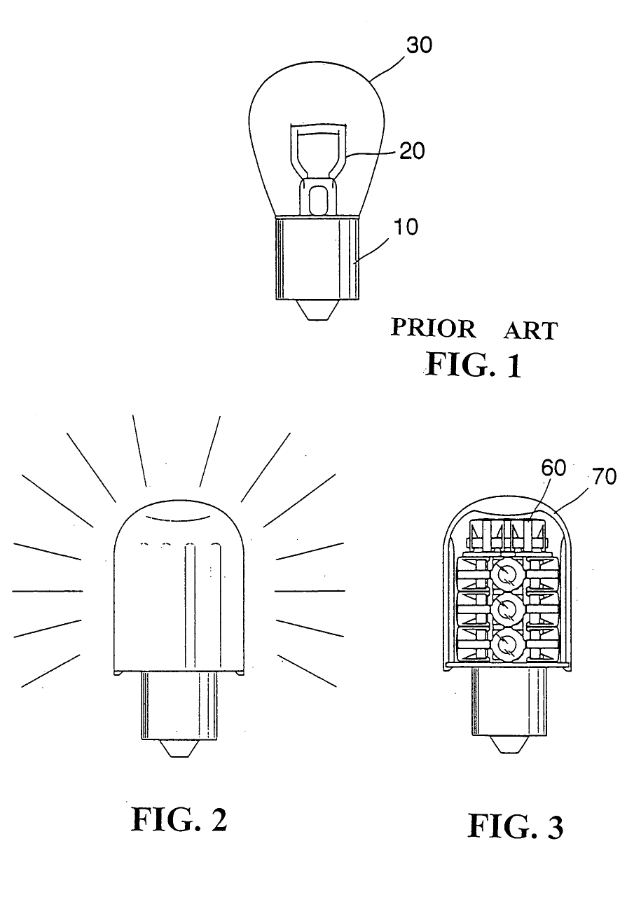

FIG. 1 is a conventional LED bulb.

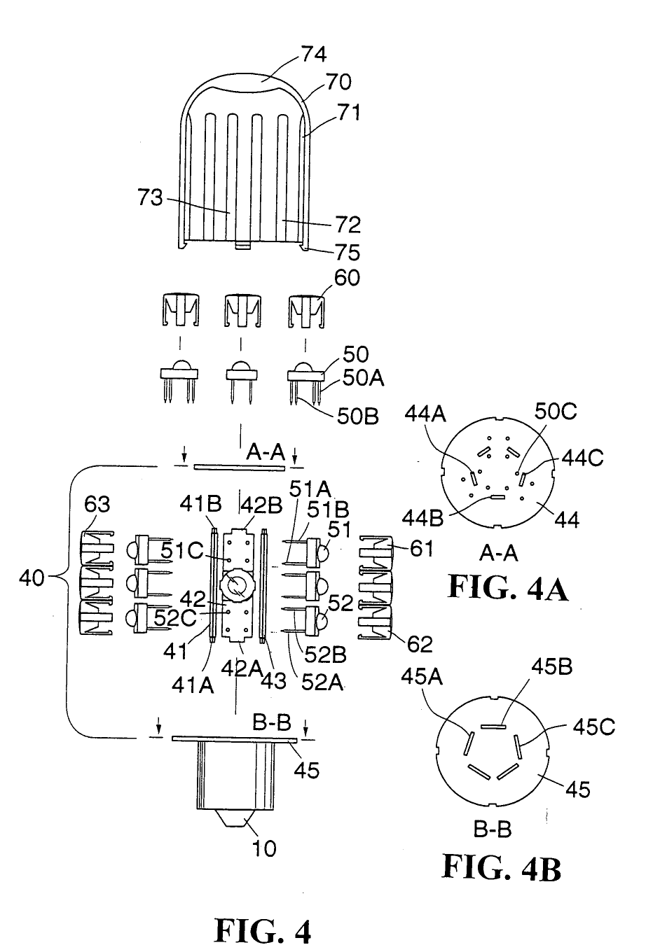

FIG. 2 is a perspective view of the gain structure of the LED in accordance with the present invention. As shown in FIGS. 3 and 4, the gain structure of the LED of the present invention comprises an LED seat block 40, a plurality of square LEDs 50, 51, 52 and a dual-layered transparent hood (the first layer transparent hood 60, 61, 62, 63, the second transparent hood 70). As shown in FIGS. 4, 4A and 4B, the LED seat block 40 includes a top plate 44 and a bottom plate 45 having a plurality of vertical plates 41, 42, 43, and the two ends of the vertical plates 41, 42, 43 are formed into engaging hood 41A, 41B, 42A, 42B. The top plate 44 and the bottom plate 45 corresponding to the vertical plates 41, 42, 43 are provided with engaging holes 44A, 44B, 44C, 45A, 45B, 45C for engaging with the engaging hook 41A, 41B, 42A, and the vertical plates 41, 42, 43 and the top plate 44 are provided with conductive pins 50A, 50B, 51A, 51B, 52A, 52B of the square LEDs 50, 51, 52 for the engagement with insertion holes 50C, 51C, 52C. The surrounding of the holes 50C, 51C, 52C are conductive wires for the soldering with the conductive pins 50A, 50B, 51A, 51B, 52A, 52B. The bottom plate 45 is connected to the other ends of the vertical plates 41, 42, 43 protruded from the conductive cylinder 10, and is normally mounted onto a bulb seat. The first layer transparent hoods 60, 61, 62, 63 have a hood body covered the square LEDs 50, 51, 52. The outer of the first-layer transparent hoods 60, 61, 62, 63 is then covered with the second transparent hood 70. The internal surrounding of the second transparent hood 70 is a transparent internal teeth straps 71, 72, 73. The center of the top of the second transparent hood 70 is formed into convex lens 74, and the hood opening of the transparent hood 70 can exactly seal by the bottom plate 45. The inner edge of the hood opening is formed into a plurality of inverted hooks 75 for engagement with the bottom plate 45. Melted glue is used to seal the inverted hook 75 so that a water proof is obtained. FIGS. 2 and 3 indicate a sealed body.

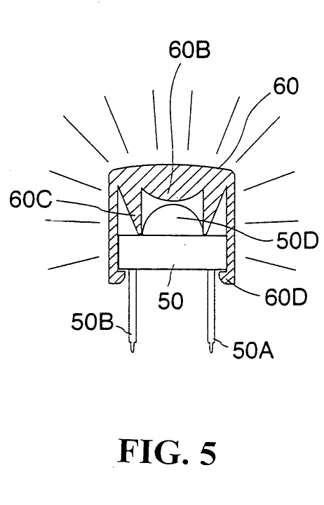

The mounting of the first transparent hoods 60, 61, 62, 63 and that of the plurality of the square LEDs 50, 51, 52 are identical. For example, as shown in FIG. 5, where the first transparent hood 60 and the LED 50 are used as example. The transparent hood 60 covers the tip 50D of the square LED 50, and then the transparent hood 60 corresponding to the tip 50D is formed into a convex lens 60B. The surrounding of convex lens 60B is a transparent rim 60C for urging with the tip 50D of LED 50. The external edge of the rim 60C is vertically fastened to the inverted rim 60D of the bottom edge of the LED 50. When in mass production, the LED 50 and the first transparent hood 60 are mounted to form a single complete component.

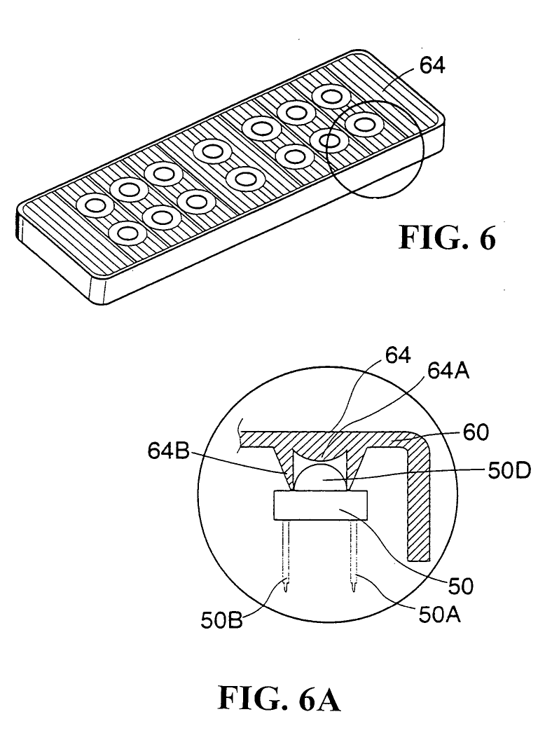

FIG. 6 and 6A illustrate a second preferred embodiment in accordance with the present invention. The first transparent hood 60 is a warning light hood 64 provided with a plurality of square LED 50, and then a first-transparent hood 64 corresponding to the tip 50D of the LED 50 is formed into a convex lens 64A.

The surrounding of the convex lens 64A is transparent rim 64B for urging with the tip 50D of the LED. Thus a large area LED is formed.

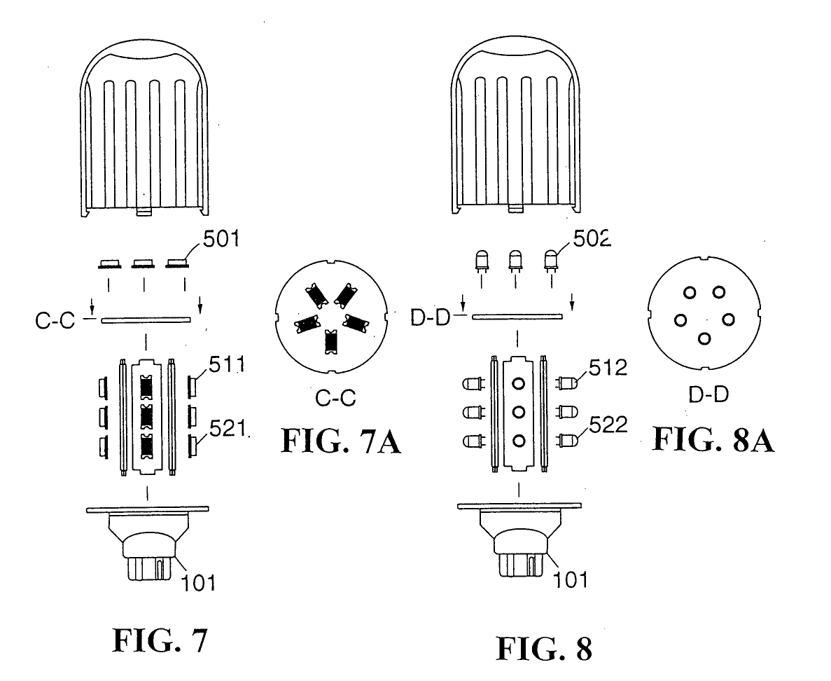

FIGS. 7 and 7A illustrate a third preferred embodiment according to the present invention. As shown, the square LEDs are replaced with chip LEDs 501, 511, 521 . . . or 5 mm SMD LEDs 502, 512, 522, . . . (see FIGS. 8 and 8A). Furthermore, the conductive cylinder 10 is replaced with a flat conductive member for meeting different needs.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

1. A gain structure of an LED comprising an LED seat block, a plurality of square LEDs, and two layered transparent hood, characterized in that the conductive pins of the LEDs are soldered to corresponding conductive wire of the seat block and the first transparent hood covers the tip of the square LEDs, and the tip of the LEDs is provided with a convex lens, the surrounding of the convex lens is protruded to urge the transparent rim of the tip of the LEDs, and the external of the first transparent hood is provided with a second transparent hood and the internal surrounding of the second transparent hood is provided with a transparent internal teeth strap, and the center of the top of the second transparent hood is formed into a convex lens.

2. A gain structure of an LED comprising the first block, a plurality of square LEDs, and two layered transparent hood, characterized in that the conductive pins of the LEDs are soldered to corresponding conductive wire of the seat block and the first transparent hood covers the tip of the square LEDs, and the tip of the LEDs is provided with a convex lens, the surrounding of the convex lens is protruded to urge the transparent rim of the tip of the LEDs.

3. The gain structure of LED of claim 1, wherein the LED seat block includes a top plate and a bottom plate having a plurality of vertical plates at the center thereof, and the two ends of the vertical plates are formed into engaging hook, and the top plate and the bottom plate corresponding to the vertical plates are provided with engaging hole for engaging with an engaging plate, and the vertical plate and the top plate are also provided with insertion holes for mounting with conductive pins of the square LEDs and the surrounding of the insertion hole is provided with conductive wires for soldering with the conductive pins, and the other end of the vertical plate mounted to the bottom plate is formed into a conductive cylinder such that the bottom plate is mounted to a bulb seat.

4. The gain structure of LED of claim 3, wherein the hood opening of the second transparent hood is sealed to the bottom plate and the inner edge of the hood opening urges the inverted hooks at the bottom edge of the base plate.

5. The gain structure of LED of claim 1, wherein the external edge of the rim of the first transparent hood is vertically mounted with inverted rim of the bottom edge of the square LEDs.

6. The gain structure of LED of claim 1, wherein said square LEDs are replaced with chip LEDs or 5 mm SMD LEDs.

7. The gain structure of LED of claim 1, wherein said conductive cylinder is replaced with a flat conductive member.
